(19) United States
(12) Patent Application Publication
(10) Pub. No.: US 2008/0160741 A1
(43) Pub. Date: Jul. 3, 2008

(54) METHOD OF MANUFACTURING SEMICONDUCTOR DEVICE

(75) Inventor: Byoung Ju KANG, Anyang-si (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/933,925

(22) Filed: Nov. 1, 2007

(30) Foreign Application Priority Data
Dec. 29, 2006 (KR) 10-2006-0137282

(51) Int. Cl. H01L 21/28

(52) U.S. Cl. 438/589; 257/E21.177

(57) ABSTRACT

A method of manufacturing a semiconductor device comprising forming a plurality of trench gate electrodes in a semiconductor substrate which protrude from the semiconductor substrate by a predetermined height; forming a polycrystal silicon film on the surface of the substrate; performing an anisotropic etching process on the polycrystal silicon film so as to expose the upper surfaces of the trench gate electrodes and to form spacers on each side of the trench gate electrodes; forming an insulating film on the substrate; forming a plurality of first photoresist patterns; etching the insulating film using the first photoresist patterns in order to form a plurality of insulating film patterns with spaces being formed between the plurality of insulating film patterns; and forming metal film patterns in the spaces between the insulating film patterns in order to form a series of contacts which correspond to the trench gate electrodes.

### CROSS-REFERENCES AND RELATED APPLICATIONS

This application claims the benefit of Korean Patent Application No. 10-2006-0137282, filed on 29 Dec. 2006, which is hereby incorporated by reference in its entirety.

### BACKGROUND OF THE INVENTION

1. Field of the Invention

The present invention relates to a method of manufacturing a semiconductor device. More particularly, the present invention relates to a method of manufacturing a semiconductor device, which is capable of preventing deteriorated electrical characteristics due to misalignments which may occur when a transistor with a trench gate structure is formed during the semiconductor manufacturing process.

2. Discussion of the Related Art

In general, as semiconductor devices have become more highly integrated, the size and channel lengths of the devices have decreased. One difficulty however, is that as the channel lengths of the semiconductor device have decreased, various undesired electrical properties have emerged, including short channel effects. In order to suppress the short channel effects, the length of the gate electrode the thickness of the gate insulating film and depth of the source and drain should be reduced. Additionally, in relation to the decrease in the length of the gate and the thickness of the gate insulating film, the amount of voltage applied should be decreased while the doping concentration of the semiconductor substrate should be increased. In particular, the doping profile of the channel region should be efficiently controlled.

One difficulty is that as the size of the semiconductor device is reduced, the amount of power required to operate the electronic product remains relatively high. Accordingly, as illustrated in an example containing an NMOS transistor, the electrons injected from the source area are quickly accelerated using a high potential gradient in a drain, resulting in a weak structure wherein hot carriers are likely to occur. In order to reduce this variation in the electric field due to the hot carriers, a lightly doped drain (LDD) structure is often used, wherein a graded junction in the source and drain regions are formed in the substrate on either side of a gate electrode, so that a low ion-implantation concentration is formed near the edges of the gate electrode while a high ion-implantation concentration remains in the centers of the source and drain regions.

One method for improving the electronic properties of a MOS transistor while reducing the length of the gate electrode involves forming a trench gate in the MOS transistor, wherein a trench is formed in a substrate and filled with a gate electrode, unlike standard MOS transistors wherein the gate electrode is formed on the surface of a substrate. One difficulty in forming the trench gate, however, is that misalignments can occur during the manufacturing process, as shown in FIG. 1A. Typically the trench of gate electrodes are formed using photoresist patterns during a process for forming contacts by filling and area with metal in order to form an electrical connection with conductive layers of the gate electrodes. Unfortunately, however, misalignments often occur during the photoresist pattern forming process.

When such misalignments occur, as shown in FIG. 1B, when the insulating film is dry-etched using the misaligned photoresist patterns, regions A are formed wherein the substrate is exposed, meaning that the misalignments create problems during the subsequent process when the contact are formed, resulting in a large number of semiconductor devices with defects created during the manufacturing process.

### BRIEF SUMMARY OF THE INVENTION

Accordingly, the present invention is directed to a method of manufacturing a semiconductor device that substantially obviates one or more the problems, limitations, or disadvantages of the related art.

An object of the present invention is to provide a method of manufacturing a semiconductor device that prevents deteriorated electrical properties due to misalignments formed during the manufacturing process in a transistor with a trench gate structure.

Additional advantages, objects, and features of the invention will be set forth in part in the description which follows and in part will become apparent to those having ordinary skill in the art or may be learned from practice of the invention. Thus, objectives and other advantages of the invention may be realized and attained using the structure particularly pointed out in the written description and claims an illustrated in the appended drawings.

To achieve these and other objects and advantages of the invention, as embodied and broadly described herein, one aspect of the invention is a method of manufacturing a semiconductor device. The method comprises forming a plurality of trench gate electrodes in a semiconductor substrate, the trench gate electrodes protruding from the semiconductor substrate by a predetermined height; forming a polycrystal silicon film on the surface of the substrate; performing an anisotropic etching process on the polycrystal silicon film so as to expose upper surface of the trench gate electrodes and to form spacers on each side of the trench gate electrodes; forming an insulating film on the surface of the substrate; forming a plurality of first photoresist patterns on the insulating film; etching the insulating film using the first photoresist patterns in order to form a plurality of insulating film patterns with spaces being formed between the plurality of insulating film patterns; and forming metal film patterns in the spaces between the insulating film patterns in order to form a series of electrical contacts corresponding to the trench gate electrodes.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention are incorporated in and constitute a part of this application.

The drawings illustrate embodiment(s) of the invention and together with the description serve to explain the principle of the invention. In the drawings:

FIGS. 1A and 1B are cross-sectional views illustrating problems which may occur in conventional methods of manufacturing a semiconductor device; and

FIGS. 2A to 2H are cross-sectional views illustrating a method of manufacturing a semiconductor device according to an embodiment of the present invention.

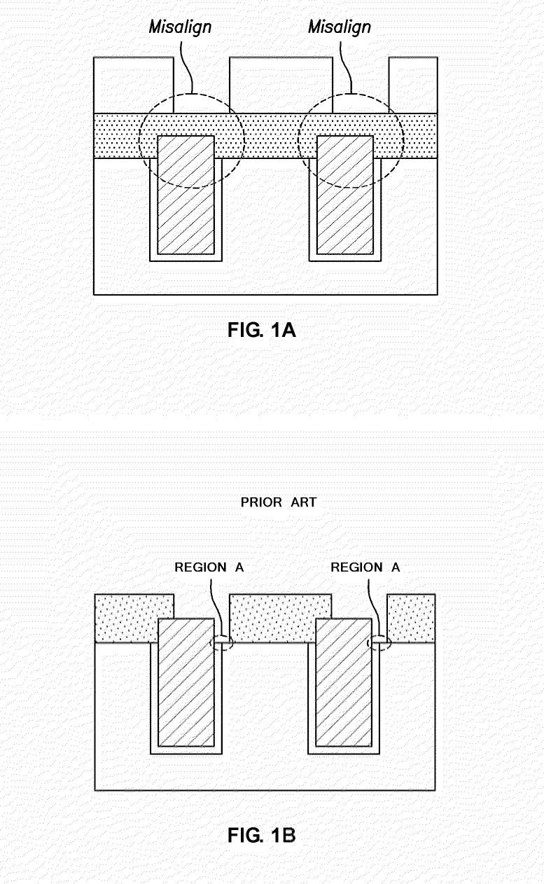

### DETAILED DESCRIPTION OF THE INVENTION

Hereinafter, a method of manufacturing a semiconductor device according to an embodiment of the present invention will be described with reference to the accompanying drawings.

In this description, technology which is widely known to the related technical field that is not directly related or relevant to the present invention will be omitted so as to clarify the scope of the present invention without unnecessarily obscuring the scope of the present invention with unnecessary description.

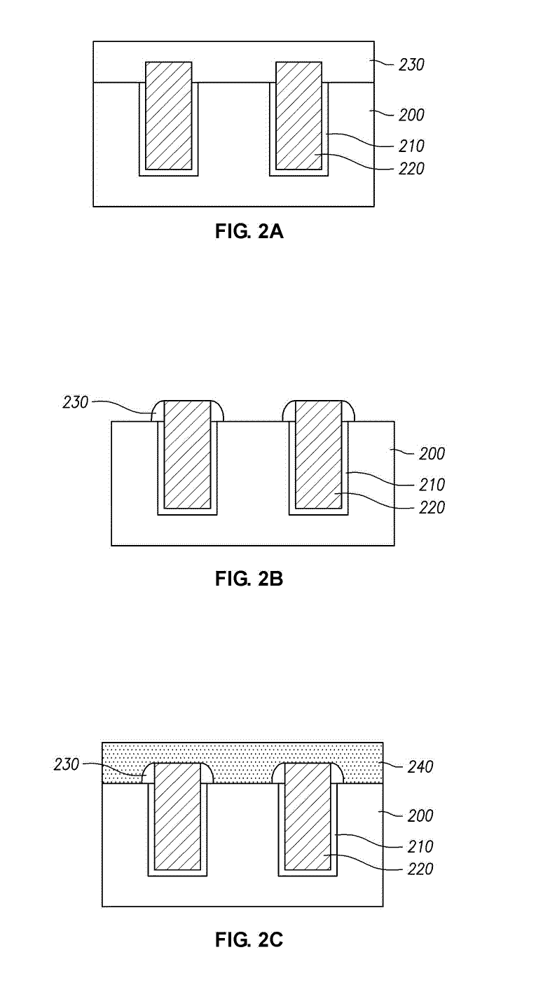

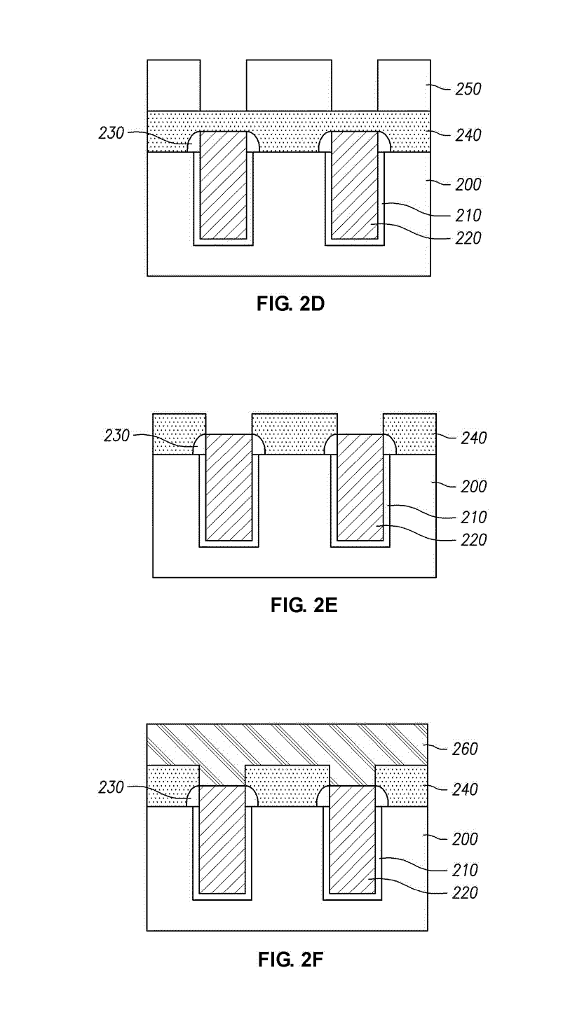

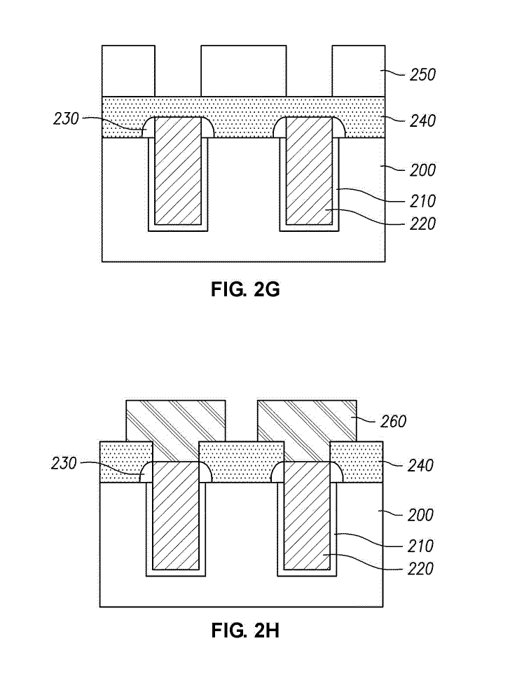

First, as shown in FIG. 2A, a plurality of trench gate electrodes 220 are formed in a semiconductor substrate 200. Here, the trench gate electrodes 220 protrude from the semiconductor substrate 200 by a predetermined height of between 800 and 1200 Å. Then, a second polycrystal silicon film 230 is formed on the entire surface of the substrate 200 wherein the trench gate electrodes 220 are formed.

Now, a method of forming the trench gate electrodes 220 will be briefly described. First, a plurality of photoresist patterns for defining trenches are formed on the semiconductor substrate 200. Subsequently, the substrate 200 is etched using the photoresist patterns using a reactive ion etching (RIE) process, so as to form the trenches according to predetermined design. In this configuration, the depth of the trenches is preferably between 14000 and 18000 Å.

Next, a thermal oxidation process is performed with respect to the trenches so as to grow a thin SiO₂ layer in order to form gate insulating films 210.

Subsequently, a first polycrystal silicon film is formed so as to bury the trenches in which the gate insulating films 210 are formed and a planarization process is performed with on the first polycrystal silicon film until the photoresist patterns are exposed. In one configuration, the planarization process may be performed using a chemical and mechanical polishing process or an etch-back process.

Subsequently, the photoresist patterns for defining the trenches are removed. Next, as shown in FIG. 2B, an anisotripic etching process, such as a blanket etching process, is performed on the second polycrystal silicon film 230 without using a photoresist pattern as a mask. The process continues until the upper surfaces of the trench gate electrodes 220 are exposed, such that spacers formed of the second polycrystal silicon film 230 are formed on each side of the trench gate electrodes 220. That is, the height of the spacers are formed to be equal to the height of the trench gate electrodes 220 protruding from the substrate 200. Thus the height of the spacers is preferably between 800 and 1200 Å.

Accordingly, since the polycrystal silicon spacers are formed on each side of the trench gate electrodes 220, it is possible to minimize any misalignments due to overlay margins which may occur during the subsequent photoresist pattern forming process for forming contacts capable of electrically connecting the conductive layers to the trench gate electrodes 220.

Next, as shown in FIG. 2C, an insulating film 240 is formed on the entire surface of the substrate 200 wherein the trench gate electrodes 220 and spacers are formed. Here, the insulating film 240 is preferably formed of any material selected from the group of thermal oxide materials, a boro-phospho silicate glass (BPSG) materials, and a low-k (low dielectric) insulating materials.

Subsequently, as shown in FIG. 2D, a photoresist film is formed on the insulating film 240 in a predetermined pattern so as to form a plurality of first photoresist patterns 250 in order to define a contact area. That is, in order to form passages for the contacts for electrically connecting the conductive layers of the gate electrodes, the photoresist pattern forming process is performed. As described above, although the misalignments may cause overlay margin occurs in the photoresist pattern forming process of the current art, it is possible to minimize the effect of the misalignments using the spacers formed on each side of the trench gate electrodes 220.

Subsequently, as shown in FIG. 2E, the insulating film 240 is dry-etched using the photoresist patterns 250 in order to define a trench for the contacts, such that a plurality of insulating film patterns are formed.

Accordingly, by forming the spacers of polycrystal silicon film 230 on each side of the trench gate electrodes 220, it is possible to minimize the effects of any misalignments due to a overlay margin.

Next, as shown in FIG. 2F, a metal film 260 is formed so as to sufficiently fill the spaces between the plurality of insulating film patterns. Then, as shown in FIG. 2G, in order to allow the contacts to connect to the trench gate electrodes 220, a second series of photoresist patterns 270 are formed on the metal film 260. Then, as shown in FIG. 2H, the metal film 260 is etched using the second photoresist patterns 270. Then, metal film patterns are formed between the insulating film patterns so as to form contacts which correspond to each trench gate electrodes 220.

As described above, since polycrystal silicon spacers are formed on each side of the trench gate electrodes protruding from the semiconductor substrate at a predetermined height, it is possible to minimize any misalignment errors due to any overlay which may occur in a subsequent photoresist pattern forming process for forming contacts in order to form a electrical connection with gate electrodes. Advantageously, this makes it possible to prevent metal resistance and the formation of a channel during the manufacturing process of the semiconductor device, resulting in improved electrical properties in the devices and an improved production yield.

It will be apparent to those skilled in the art that various modifications and variations can be made in the present invention without departing from the spirit or scope of the invention. Thus, it is intended that the present invention covers any modifications and variations of the invention that come within the scope of the appended claims and their equivalents.

What is claimed is:

1. A method of manufacturing a semiconductor device, the method comprising:
forming a plurality of trench gate electrodes in a semiconductor substrate, the trench gate electrodes protruding from the semiconductor substrate at a predetermined height;
forming a polycrystal silicon film on the entire surface of the substrate wherein the trench gate electrodes are formed;
performing an anisotropic etching process on the polycrystal silicon film so as to expose an upper surface of the trench gate electrodes, in order to form spacers on each sides of the trench gate electrodes;
forming an insulating film on the surface of the substrate wherein the trench gate electrodes and spacers are formed;
forming a plurality of photoresist patterns on the insulating film;
etching the insulating film using the photoresist patterns so as to form a plurality of insulating film patterns; and
forming metal film patterns in the area between the insulating film patterns so as to form a series of contacts capable of electrically connecting to the trench gate electrodes.

2. The method according to claim 1, wherein the forming the metal film patterns comprises:
filling the spaces between the plurality of insulating film patterns with a metal film;
forming a second series of photoresist patterns on the metal film; and
etching the metal film using the second photoresist patterns to form the metal film patterns so as to form the series of contacts capable of electrically connecting to the trench gate electrodes.

3. The method according to claim 1, wherein forming the spacers comprises performing an anisotropic etching process including a blanket etching process.

4. The method according to claim 1, wherein the insulating film patterns are formed using any material selected from the group of a thermal oxide material, a boro-phospho silicate glass (BPSG) material, and a low-k insulating material.

5. The method according to claim 1, wherein the trench gate electrodes protrude from the substrate is at a predetermined height of between 800 and 1200 Å.

6. The method according to claim 1, wherein the height of the spacers is equal to the predetermined height of the trench gate electrodes protruding from the substrate, and is between 800 and 1200 Å.

7. A method of manufacturing a semiconductor device, the method comprising:
forming a plurality of trench gate electrodes in a semiconductor substrate, the trench gate electrodes protruding from the semiconductor substrate at a predetermined height;
forming a polycrystal silicon film on the entire surface of the substrate wherein the trench gate electrodes are formed;
performing an anisotropic etching process on the polycrystal silicon film so as to expose an upper surface of the trench gate electrodes, in order to form spacers on each sides of the trench gate electrodes which protrude from the semiconductor substrate at a predetermined height equal to the predetermined height of the trench gate electrodes;
forming an insulating film on the surface of the substrate wherein the trench gate electrodes and spacers are formed;
forming a plurality of photoresist patterns on the insulating film;
etching the insulating film using the photoresist patterns so as to form a plurality of insulating film patterns with spaces between the insulating patterns;
filling the spaces between the plurality of insulating film patterns with a metal film;
forming a second series of photoresist patterns on the metal film; and
etching the metal film using the second photoresist patterns to form the metal film patterns so as to form the series of contacts capable of electrically connecting to the trench gate electrodes.

8. The method according to claim 7, wherein forming the spacers comprises performing an anisotropic etching process including a blanket etching process.

9. The method according to claim 7, wherein the insulating film patterns are formed using any material selected from the group of a thermal oxide material, a boro-phospho silicate glass (BPSG) material, and a low-k insulating material.

10. The method according to claim 1, wherein the trench gate electrodes protrude from the substrate is at a predetermined height of between 800 and 1200 Å.
